(19) United States
(12) Patent Application Publication
(10) Pub. No.: US 2023/0247127 A1
(43) Pub. Date: Aug. 3, 2023

(54) CALL SYSTEM, TERMINAL APPARATUS, AND OPERATING METHOD OF CALL SYSTEM

(71) Applicant: TOYOTA JIDOSHA KABUSHIKI KAISHA, TOYOTA-SHI (JP)

(72) Inventor: Tatsuro HORI, Tokyo-to (JP)

(73) Assignee: TOYOTA JIDOSHA KABUSHIKI KAISHA, TOYOTA-SHI (JP)

(21) Appl. No.: 18/160,590

(22) Filed: Jan. 27, 2023

(30) Foreign Application Priority Data
Feb. 2, 2022 (JP) 2022-015217

(51) Int. Cl. H04M 1/60; G06V 40/10; G06T 7/70; G10L 21/034; G10L 21/0364; G06V 40/20

(52) U.S. Cl. CPC H04M 1/60; G06V 40/10; G06T 7/70; G10L 21/034; G10L 21/0364; G06V 40/20; G06T 2207/30196

(57) ABSTRACT

A call system includes a terminal apparatus capable of inputting and outputting call audio and a server apparatus configured to relay transmission and reception of audio information including the call audio between the terminal apparatus and another terminal apparatus. The server apparatus or the terminal apparatus performs an adjustment process to adjust the audio information so as to increase a volume of the call audio that is inputted to and outputted from the terminal apparatus according to a volume of call audio inputted at the terminal apparatus or a distance from the terminal apparatus to a user.

### CROSS-REFERENCE TO RELATED APPLICATION

This application claims priority to Japanese Patent Application No. 2022-015217, filed on Feb. 2, 2022, the entire contents of which are incorporated herein by reference.

### TECHNICAL FIELD

The present disclosure relates to a call system, a terminal apparatus, and an operating method of a call system.

### BACKGROUND

Technology that enables users to hold a call by a plurality of computer terminals exchanging users' speech over a network is known. Technology has also been proposed to contribute to user convenience in a case in which a plurality of users share one terminal apparatus. For example, Patent Literature (PTL) 1 discloses technology for controlling individual voice data corresponding to a speaker selected from input voice data when a plurality of speakers input their voice to a conference voice input terminal.

### CITATION LIST

### Patent Literature

PTL 1: JP 6859807 B2

### SUMMARY

Call systems in which a plurality of users share a single terminal apparatus have room for improvement in terms of convenience.

A call system and the like that can improve convenience in a case in which a plurality of users share a single terminal apparatus are disclosed below.

A call system according to the present disclosure includes:

a terminal apparatus capable of inputting and outputting call audio; and

a server apparatus configured to relay transmission and reception of audio information including the call audio between the terminal apparatus and another terminal apparatus, wherein

the server apparatus or the terminal apparatus performs an adjustment process to adjust the audio information so as to increase a volume of the call audio that is inputted to and outputted from the terminal apparatus according to a volume of call audio inputted at the terminal apparatus or a distance from the terminal apparatus to a user.

A terminal apparatus according to the present disclosure includes:

an input/output interface configured to input and output call audio;

a communication interface; and

a controller configured to transmit and receive audio information including the call audio via the communication interface, wherein

the controller performs an adjustment process to adjust the audio information so as to increase a volume of the call audio that is inputted to and outputted from the terminal apparatus according to a volume of inputted call audio or a distance from the terminal apparatus to a user.

An operating method of a call system according to the present disclosure is an operating method of a call system including a terminal apparatus capable of inputting and outputting call audio and a server apparatus configured to relay transmission and reception of audio information including the call audio between the terminal apparatus and another terminal apparatus, the operating method including:

performing, by the server apparatus or the terminal apparatus, an adjustment process to adjust the audio information so as to increase a volume of the call audio that is inputted to and outputted from the terminal apparatus according to a volume of call audio inputted at the terminal apparatus or a distance from the terminal apparatus to a user.

According to the call system and the like in the present disclosure, user convenience can be improved in a case in which a plurality of users share a single terminal.

### BRIEF DESCRIPTION OF THE DRAWINGS

In the accompanying drawings:

FIG. 1 is a diagram illustrating a configuration example of a call system;

FIG. 2A is a sequence diagram illustrating an operation example of the call system;

FIG. 2B is a sequence diagram illustrating an operation example of the call system;

FIG. 3 is a flowchart for an adjustment process;

FIG. 4 is a flowchart for an adjustment process;

FIG. 5A is a sequence diagram illustrating an operation example in a variation of the call system; and

FIG. 5B is a sequence diagram illustrating an operation example in a variation of the call system.

### DETAILED DESCRIPTION

Embodiments are described below.

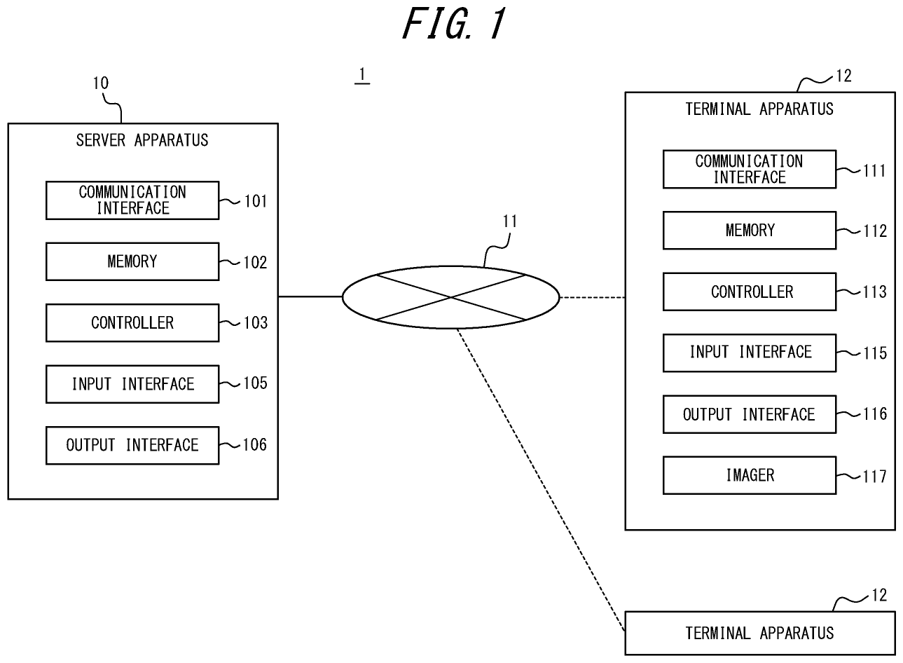

FIG. 1 is a diagram illustrating an example configuration of a call system 1 in an embodiment. The call system 1 includes a plurality of terminal apparatuses 12 and a server apparatus 10 that are connected via a network 11 to enable communication of information with each other. The call system 1 enables users of the terminal apparatus 12 to call each other using their respective terminal apparatuses 12.

The server apparatus 10 is, for example, a server computer that belongs to a cloud computing system or other computing system and functions as a server that implements various functions. The server apparatus 10 may be configured by two or more server computers that are communicably connected to each other and operate in cooperation. The server apparatus 10 relays the transmission and reception of information necessary for calls between the terminal apparatuses 12 and performs various types of information processing.

The terminal apparatuses 12 are information processing apparatuses provided with communication functions and audio input/output functions and are used by users to call each other via the server apparatus 10. Each terminal apparatus 12 is, for example, an information processing terminal, such as a smartphone or a tablet terminal, or an information processing apparatus, such as a personal computer.

The network 11 may, for example, be the Internet or may include an ad hoc network, a local area network (LAN), a metropolitan area network (MAN), other networks, or any combination thereof.

In the call system 1, the terminal apparatus 12 that is capable of inputting and outputting call audio, or the server apparatus 10 that is configured to relay the transmission and reception of audio information including the call audio between a plurality of terminal apparatuses 12, performs an adjustment process to adjust the audio information so as to increase the volume of the call audio that is inputted to and outputted from the terminal apparatus 12 according to the volume of call audio inputted at each terminal apparatus 12 or the distance from the terminal apparatus 12 to the user.

When a plurality of users share a terminal apparatus 12, the distance between each user and the terminal apparatus 12 varies. If the user making the call (hereinafter referred to as the caller for convenience) is farther away from the terminal apparatus 12 than other users, or if the volume of the caller's speech is lower than a certain level, then the volume of the call audio inputted to the terminal apparatus 12 may be lower than a certain level. In such a case, according to the adjustment process, the volume of the call audio inputted to the terminal apparatus 12 is adjusted to increase based on the volume of the call audio (this process being referred to as a caller-side adjustment process). Therefore, audio information that increases the volume of the call audio to be outputted on the terminal apparatus 12 of the called party can be transmitted to the terminal apparatus 12 of the called party. This makes it easier for the called party to hear the call audio of the caller. The convenience for the user can thereby be increased.

When the terminal apparatus 12 is shared by a plurality of users, a user who is farther away from the terminal apparatus 12 than other users may have difficulty hearing, since the volume of the call audio of the called party, outputted from the terminal apparatus 12, is attenuated and reduced. In such a case, according to the adjustment process, the volume of the call audio outputted from the terminal apparatus 12 is adjusted to increase based on the distance from the terminal apparatus 12 to the user (this process being referred to as a called party-side adjustment process). Therefore, the call audio of the called party can be made easier to hear for a user who is distant from the terminal apparatus 12. The convenience for the user can thereby be increased.

Respective configurations of the server apparatus 10 and the terminal apparatuses 12 are described in detail.

The server apparatus 10 includes a communication interface 101, a memory 102, a controller 103, an input interface 105, and an output interface 106. These configurations are appropriately arranged on two or more computers in a case in which the server apparatus 10 is configured by two or more server computers.

The communication interface 101 includes one or more interfaces for communication. The interface for communication is, for example, a LAN interface. The communication interface 101 receives information to be used for the operations of the server apparatus 10 and transmits information obtained by the operations of the server apparatus 10. The server apparatus 10 is connected to the network 11 by the communication interface 101 and communicates information with the terminal apparatuses 12 via the network 11.

The memory 102 includes, for example, one or more semiconductor memories, one or more magnetic memories, one or more optical memories, or a combination of at least two of these types, to function as main memory, auxiliary memory, or cache memory. The semiconductor memory is, for example, Random Access Memory (RAM) or Read Only Memory (ROM). The RAM is, for example, Static RAM (SRAM) or Dynamic RAM (DRAM). The ROM is, for example, Electrically Erasable Programmable ROM (EEPROM). The memory 102 stores information to be used for the operations of the server apparatus 10 and information obtained by the operations of the server apparatus 10.

The controller 103 includes one or more processors, one or more dedicated circuits, or a combination thereof. The processor is a general purpose processor, such as a central processing unit (CPU), or a dedicated processor, such as a graphics processing unit (GPU), specialized for a particular process. The dedicated circuit is, for example, a field-programmable gate array (FPGA), an application specific integrated circuit (ASIC), or the like. The controller 103 executes information processing related to operations of the server apparatus 10 while controlling components of the server apparatus 10.

The input interface 105 includes one or more interfaces for input. The interface for input is, for example, a physical key, a capacitive key, a pointing device, a touch screen integrally provided with a display, or a microphone that receives audio input. The input interface 105 accepts operations to input information used for operation of the server apparatus 10 and transmits the inputted information to the controller 103.

The output interface 106 includes one or more interfaces for output. The interface for output is, for example, a display or a speaker. The display is, for example, a liquid crystal display (LCD) or an organic electro-luminescent (EL) display. The output interface 106 outputs information obtained by the operations of the server apparatus 10.

The functions of the server apparatus 10 are realized by a processor included in the controller 103 executing a control program. The control program is a program for causing a computer to function as the server apparatus 10. Some or all of the functions of the server apparatus 10 may be realized by a dedicated circuit included in the controller 103. The control program may be stored on a non-transitory recording/storage medium readable by the server apparatus 10 and be read from the medium by the server apparatus 10.

Each terminal apparatus 12 includes a communication interface 111, a memory 112, a controller 113, an input interface 115, an output interface 116, and an imager 117.

The communication interface 111 includes a communication module compliant with a wired or wireless LAN standard, a module compliant with a mobile communication standard such as LTE, 4G, or 5G, or the like. The terminal apparatus 12 connects to the network 11 via a nearby router apparatus or mobile communication base station using the communication interface 111 and communicates information with the server apparatus 10 and the like over the network 11.

The memory 112 includes, for example, one or more semiconductor memories, one or more magnetic memories, one or more optical memories, or a combination of at least two of these types. The semiconductor memory is, for example, RAM or ROM. The RAM is, for example, SRAM or DRAM. The ROM is, for example, EEPROM. The memory 112 functions as, for example, a main memory, an auxiliary memory, or a cache memory. The memory 112 stores information to be used for the operations of the controller 113 and information obtained by the operations of the controller 113.

The controller 113 has one or more general purpose processors, such as CPUs or Micro Processing Units (MPUs), or one or more dedicated processors, such as GPUs, that are dedicated to specific processing. Alternatively, the controller 113 may have one or more dedicated circuits such as FPGAs or ASICs. The controller 113 is configured to perform overall control of the operations of the terminal apparatus 12 by operating according to the control/processing programs or operating according to operation procedures implemented in the form of circuits. The controller 113 then transmits and receives various types of information to and from the server apparatus 10 and the like via the communication interface 111 and executes the operations according to the present embodiment.

The input interface 115 includes one or more interfaces for input. The interface for input may include, for example, a physical key, a capacitive key, a pointing device, and/or a touch screen integrally provided with a display. The interface for input may also include a microphone that accepts audio input. Microphones include directional microphones, microphone arrays, and other configurations capable of detecting the direction of sound sources. The interface for input may further include a scanner, camera, or IC card reader that scans an image code. The input interface 115 accepts operations for inputting information to be used in the operations of the controller 113 and transmits the inputted information to the controller 113.

The output interface 116 includes one or more interfaces for output. The interface for output may include, for example, a display or a speaker. The display is, for example, an LCD or an organic EL display. The output interface 116 outputs information obtained by the operations of the controller 113.

The imager 117 includes a camera that captures an image of a subject using visible light and a distance measuring sensor that measures the distance to the subject to acquire a distance image. The camera captures a subject at, for example, 15 to 30 frames per second to produce a moving image formed by a series of captured images. Distance measurement sensors include ToF (Time Of Flight) cameras, LiDAR (Light Detection And Ranging), and stereo cameras and generate images of a subject that contain distance information. The imager 117 transmits the captured images and the distance images to the controller 113.

The functions of the controller 113 are realized by a processor included in the controller 113 executing a control program. The control program is a program for causing the processor to function as the controller 113. Some or all of the functions of the controller 113 may be realized by a dedicated circuit included in the controller 113. The control program may be stored on a non-transitory recording/storage medium readable by the terminal apparatus 12 and be read from the medium by the terminal apparatus 12.

In the present embodiment, the controller 113 acquires a captured image and a distance image of the user of the terminal apparatus 12 with the imager 117 and collects audio of the speech of the user with the microphone of the input interface 115. The controller 113 generates encoded information by encoding the captured images and distance images of the user and speech information for reproducing the participant's speech and transmits the encoded information to another terminal apparatus 12 via the server apparatus 10 using the communication interface 111. The controller 113 may perform any appropriate processing (such as resolution change and trimming) on the captured images and the like at the time of encoding. When the controller 113 receives encoded information transmitted from the other terminal apparatus 12 via the server apparatus 10 using the communication interface 111, the controller 113 decodes the encoded information. The controller 113 then uses the decoded information to form an image of the called party who is using the other terminal apparatus 12 and displays the image on the display of the output interface 116. The image of the called party may be a 3D model, and an image of a virtual space obtained by placing the 3D model in the virtual space may be displayed. The controller 113 also outputs call audio from the speaker of the output interface 116 based on the decoded audio information.

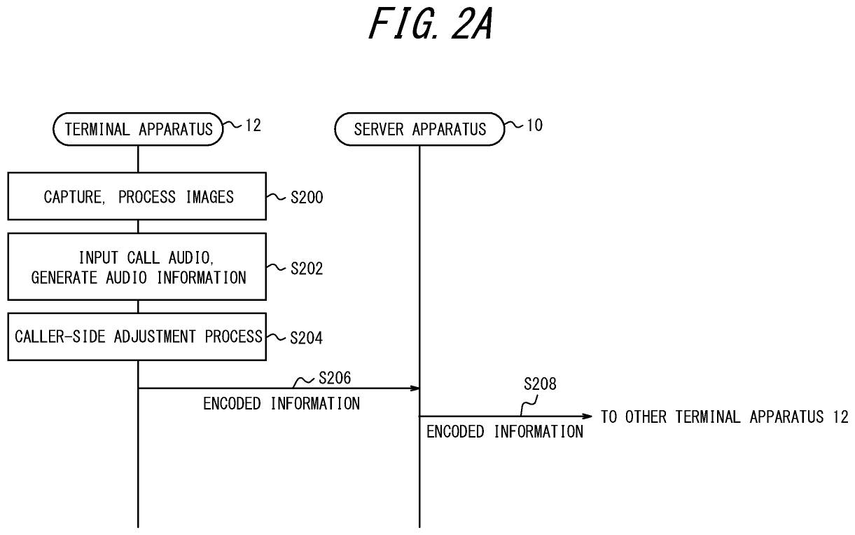

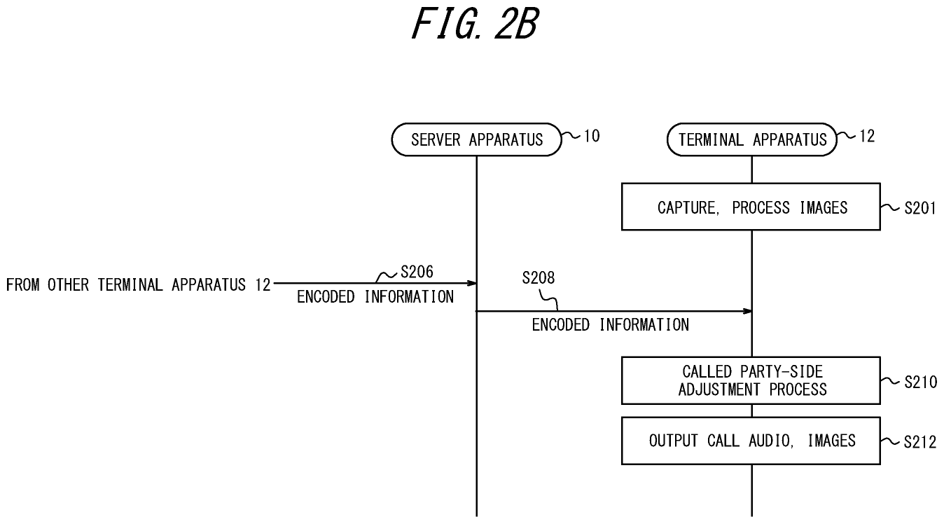

FIGS. 2A, 2B are a sequence diagram illustrating the operation procedures of the call system 1. The steps pertaining to the various information processing by the server apparatus 10 and the terminal apparatuses 12 in FIGS. 2A, 2B are performed by the respective controllers 103 and 113. The steps pertaining to transmitting and receiving various types of information to and from the server apparatus 10 and the terminal apparatuses 12 are performed by the respective controllers 103 and 113 transmitting and receiving information to and from each other via the respective communication interfaces 101 and 111. In the server apparatus 10 and the terminal apparatuses 12, the respective controllers 103 and 113 appropriately store the transmitted and received information in the respective memories 102 and 112. Furthermore, the controller 113 of the terminal apparatus 12 accepts input of various types of information with the input interface 115 and outputs various types of information with the output interface 116.

The procedures in FIG. 2A illustrate the procedures involved in the coordinated operation of the server apparatus 10 and the terminal apparatus 12 when a user inputs call audio to the terminal apparatus 12 and the terminal apparatus 12 transmits audio information on the call audio.

In step S200, the terminal apparatus 12 captures images of the user, or the user and other users, and performs image processing on the captured images. The controller 113 acquires images captured by visible light and distance images at any appropriate frame rate from the imager 117 and performs various processing such as edge detection, feature point detection, and distance detection on the images. The processed information is used in the caller-side adjustment process, described below.

In step S202, the terminal apparatus 12 receives input of the call audio of the user who is speaking, i.e., the caller, and generates audio information. The controller 113 controls the input interface 115 to collect the call audio and generates audio information based on the information transmitted by the input interface 115.

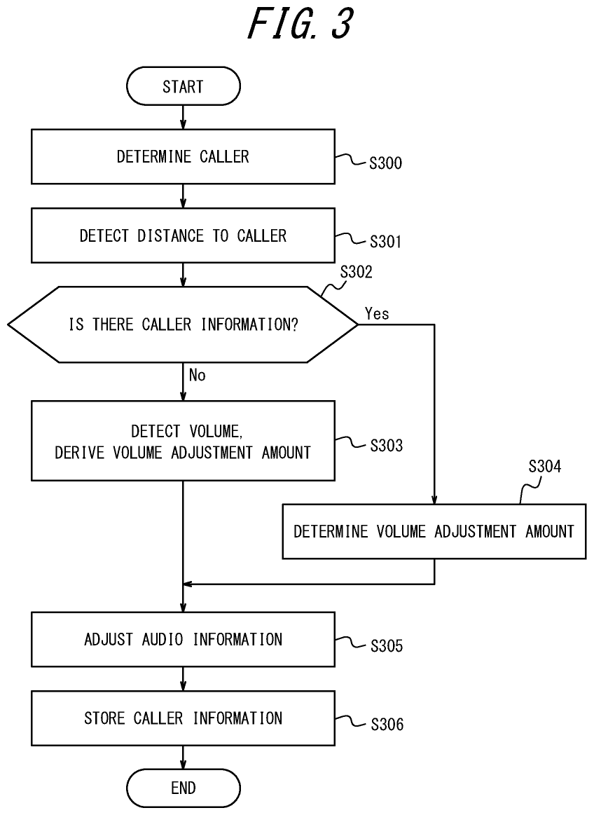

In step S204, the terminal apparatus 12 performs a caller-side adjustment process on the audio information. The detailed procedures of the caller-side adjustment process are described in FIG. 3.

In step S206, the terminal apparatus 12 encodes the adjusted audio information and the captured image, groups the encoded information in packets, and transmits the packets to the server apparatus 10. The server apparatus 10 receives the information from the terminal apparatus 12.

In step S208, the server apparatus 10 transmits the packets of encoded information transmitted by the terminal apparatus 12 to the terminal apparatus 12 of the called party.

The procedures in FIG. 2B illustrate the procedures involved in the coordinated operation of the server apparatus 10 and the terminal apparatus 12 when the terminal apparatus 12 receives audio information from another terminal apparatus and outputs the call audio of the called party.

In step S201, the terminal apparatus 12 captures images of the user, or the user and other users, and performs image processing on the captured images. The controller 113 acquires images captured by visible light and distance images at any appropriate frame rate from the imager 117 and performs various processing such as edge detection, feature point detection, and distance detection on the images. The processed information is used in the called party-side adjustment process, described below.

The packets of encoded information that the server apparatus 10 receives from the other terminal apparatus 12 in step S206 (same as in FIG. 2A) are transmitted from the server apparatus 10 in step S208 (same as in FIG. 2A) and received by the terminal apparatus 12. The terminal apparatus 12 decodes the encoded information and extracts audio information, captured images, and the like.

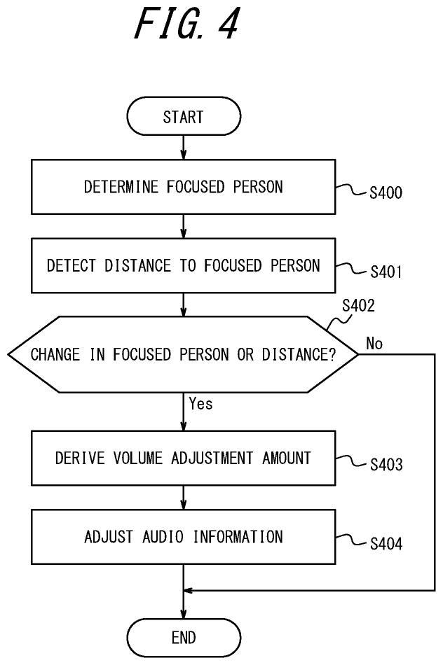

In step S210, the terminal apparatus 12 performs a called party-side adjustment process on the audio information. The detailed procedures of the called party-side adjustment process are described in FIG. 4.

In step S212, the terminal apparatus 12 outputs call audio to the user and an image of the called party. Based on the audio information, the controller 113 controls the output interface 116 to output the call audio at the volume set by the audio information. The controller 113 also forms an image of the called party based on the captured image and controls the output interface 116 to output the image of the called party.

FIG. 3 is a flowchart illustrating the operating procedures by the controller 113 of the terminal apparatus 12 for the caller-side adjustment process. The procedures in FIG. 3 correspond to the detailed procedures in step S204 of FIG. 2A. The procedures in FIG. 3 are performed in any appropriate cycles, for example, from several milliseconds to several seconds.

In step S300, the controller 113 determines the caller from the captured image. In a case in which the terminal apparatus 12 is used by one user, and only one user is included in the captured image, that user is identified as the caller, whereas in a case in which the terminal apparatus 12 is used by a plurality of users, and a plurality of users are included in the captured image, the talking user is identified as the caller. For example, the controller 113 detects people from the captured image by any appropriate image processing, such as pattern recognition, and determines the person who is speaking from among the detected people as the caller. For example, the controller 113 detects patterns of changes in the shape of a person's mouth and determines that the person is speaking when the detection result matches a preset pattern for determining speech. The controller 113 may generate a caller determination model by performing machine learning using training data consisting of captured images in which the caller is identified and may then use the model to determine the caller. The controller 113 may also detect the direction of the sound source of the call audio collected by the input interface 115 and determine the person in the captured image corresponding to that direction as the caller.

In step S301, the controller 113 detects the distance from the terminal apparatus 12 to the caller. For example, the controller 113 uses the distance image to derive the distance to the caller for the caller detected in the captured image.

In step S302, the controller 113 determines the existence of caller information for the detected caller. The caller information identifies the caller by an image of the caller and is information associated with each caller, such as the volume of the call audio of the caller, the volume adjustment amount, and the like. The controller 113 searches the history stored in the memory 112 to determine whether past caller information exists.

If there is no past caller information (step S302: NO), the controller 113 detects the volume of the call audio of the caller and derives the adjustment amount in step S303. For example, if the volume is lower than any appropriate reference value, the controller 113 derives the adjustment amount to increase the volume to the reference value. The controller 113 may also derive the adjustment amount to increase the caller's volume to any appropriate value that is equal to or greater than the average volume of unspecified callers detected in the past and is equal to or less than the maximum value. The adjustment amount may be any appropriate parameter, such as a coefficient, amount of increase, or the like with respect to the detected volume.

On the other hand, if there is past caller information (step S302: YES), the controller 113 determines the volume adjustment amount based on the caller information in step S304. The probability is high that the speech volume will tend to fall within a certain range for each caller. For example, in the case of a caller whose volume tends to be lower than average, the probability is high that a certain degree of adjustment to increase the volume will be required. Therefore, the controller 113 can determine the volume adjustment amount based on the caller information for the caller determined from the captured image. In this case, the volume adjustment amount can be determined without going through the process of detecting the caller's volume, as in step S303. Alternatively, the controller 113 may correct the adjustment amount determined from the caller information according to the distance from the microphone to the caller. For example, when a caller speaks at the same volume, the volume will decrease due to attenuation with increased distance from the microphone. Therefore, in such cases, the adjustment amount can be increased as the distance is larger. For example, a table of coefficients corresponding to distance may be stored in the memory 112, and the controller 113 may correct the adjustment amount by multiplying the adjustment amount by such coefficients.

In step S305, the controller 113 adjusts the audio information so that the volume of the call audio is increased by the determined or derived adjustment amount.

In step S306, the controller 113 updates and stores the caller information in the memory 112. A history of the new adjustment amount is added to the caller information.

FIG. 4 is a flowchart illustrating the operating procedures by the controller 113 of the terminal apparatus 12 for the called party-side adjustment process. The procedures in FIG. 4 correspond to the detailed procedures in step S210 of FIG. 2B. The procedures in FIG. 4 are performed in any appropriate cycles, for example, from several milliseconds to several seconds.

In step S400, the controller 113 determines the user who is concentrating on the call (referred to for convenience as the focused person) from the captured image. In a case in which the terminal apparatus 12 is used by one user, and only one user is included in the captured image, that user is identified as the focused person, whereas in a case in which the terminal apparatus 12 is used by a plurality of users, and a plurality of users are included in the captured image, the user whose degree of concentration on the call is the highest is identified as the focused person. For example, the controller 113 detects people from the captured image by any appropriate image processing, such as pattern recognition, and determines the person whose degree of concentration on the call is the highest from among the detected people as the focused person. For example, the controller 113 determines that a person who is gazing at the display, or who exhibits a behavior pattern indicative of concentration, such as nodding or taking notes, is concentrating on the call. The controller 113 further determines the person who has presented a behavior pattern indicative of concentration for the longest time in any period of time as the focused person. The controller 113 may generate a focused person determination model by performing machine learning using training data consisting of captured images in which the focused person is identified and may then use the model to determine the focused person.

In step S401, the controller 113 detects the distance from the terminal apparatus 12 to the focused person. For example, the controller 113 uses the distance image to derive the distance to the focused person for the focused person detected in the captured image.

In step S402, the controller 113 makes a comparison with detection results from a previous processing cycle to determine whether a change from the past focused person to a new focused person, or a change in distance to the focused person, has occurred. A change is determined to have occurred in a case in which a plurality of users share the terminal apparatus 12 and the user identified as the focused person changes, or in a case in which the focused person moves, changing the distance from the terminal apparatus 12 to the focused person. When the process in FIG. 4 begins, it is determined that a change has occurred, since no past detection results exist.

If a change has occurred (step S402: YES), the controller 113 derives the adjustment amount of the call audio according to the distance to the focused person in step S403. For example, as the focused person is farther from the speaker, the volume of the call audio that arrives is lower due to attenuation. Therefore, in such cases, the adjustment amount can be increased as the distance is larger. For example, a table of adjustment amounts corresponding to distance may be stored in the memory 112, and the controller 113 may derive the adjustment amount from the table. The adjustment amount may be any appropriate parameter, such as a coefficient, amount of increase, or the like with respect to the detected volume.

If, on the other hand, neither the focused person nor the distance to the focused person has changed (step S402: NO), the controller 113 adopts the adjustment amount derived in the previous processing cycle and proceeds to step S404.

In step S404, the controller 113 adjusts the audio information so that the volume of the call audio is increased by the derived adjustment amount.

According to the operations described above, the call audio is outputted based on audio information in which the volume of the call audio is increased by the caller-side adjustment process or the called party-side adjustment process. Therefore, even in a case in which the caller is far from the terminal apparatus 12, or the volume of the caller's speech is lower than a certain level, the call audio of the caller can still be easily heard by the called party. This also makes it easier for a focused person who is far from the terminal apparatus 12 to hear the call audio of the called party. The convenience for the user can thereby be increased.

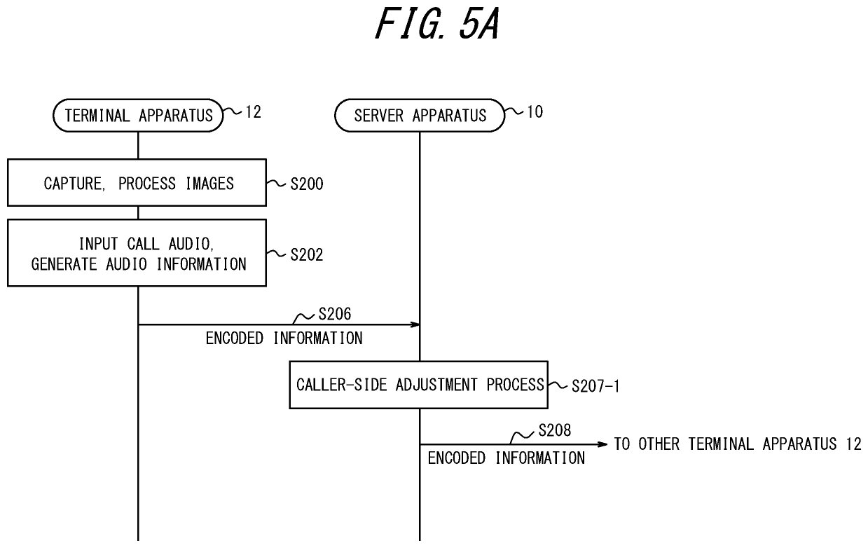

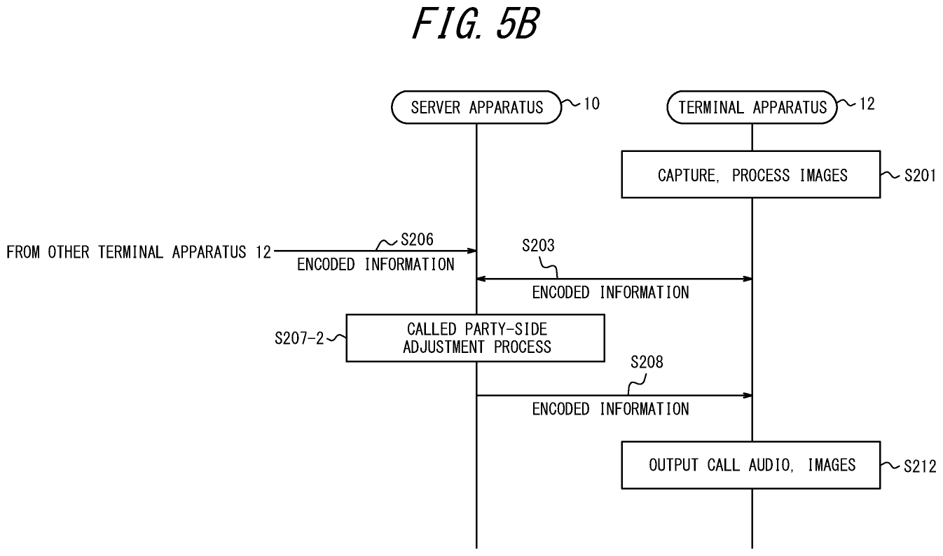

FIGS. 5A and 5B illustrate variations of the procedures in FIGS. 2A and 2B, respectively. The procedures that are the same as those in FIGS. 2A and 2B are labeled with the same reference signs, and a description is omitted where appropriate.

The variation illustrated in FIG. 5A differs from FIG. 2A in that the caller-side adjustment process is performed by the server apparatus 10 instead of the terminal apparatus 12. In step S206, the terminal apparatus 12 encodes the audio information, captured images, and the like and transmits packets of encoded information to the server apparatus 10. The server apparatus 10 decodes the information received from the terminal apparatus 12. The server apparatus 10 then performs the caller-side adjustment process in step S207-1 by executing the procedures illustrated in FIG. 3. Then, in step S208, the server apparatus 10 transmits packets of encoded information including the audio information subjected to the adjustment process, captured images, and the like to the other terminal apparatus 12. In this way, the processing load on the terminal apparatus 12 is distributed accordingly.

The variation illustrated in FIG. 5B differs from FIG. 2B in that the called party-side adjustment process is performed by the server apparatus 10 instead of the terminal apparatus 12. In step S203, the terminal apparatus 12 encodes the captured images and transmits packets of encoded information to the server apparatus 10. The server apparatus 10 decodes the information received from the terminal apparatus 12. In step S207-2, the server apparatus 10 then performs the procedures illustrated in FIG. 4 to perform the called party-side adjustment process on the audio information received from another terminal apparatus 12 in step S206. Then, in step S208, the server apparatus 10 transmits packets of encoded information including the audio information subjected to the adjustment process, captured images, and the like to the other terminal apparatus 12. In this way, the processing load on the terminal apparatus 12 is distributed accordingly.

The above description also applies to a case in which three or more terminal apparatuses 12 communicate via the server apparatus 10. For example, the audio information transmitted from one terminal apparatus 12 is subjected to the caller-side adjustment process on that terminal apparatus 12 or on the server apparatus 10. The server apparatus 10 transmits the audio information to the two or more other terminal apparatuses. At this time, the called party-side adjustment process is performed on the server apparatus 10 or on the two or more other terminal apparatuses 12.

While embodiments have been described with reference to the drawings and examples, it should be noted that various modifications and revisions may be implemented by those skilled in the art based on the present disclosure. Accordingly, such modifications and revisions are included within the scope of the present disclosure. For example, functions or the like included in each means, each step, or the like can be rearranged without logical inconsistency, and a plurality of means, steps, or the like can be combined into one or divided.

1. A call system comprising:
a terminal apparatus capable of inputting and outputting call audio; and
a server apparatus configured to relay transmission and reception of audio information including the call audio between the terminal apparatus and another terminal apparatus, wherein
the server apparatus or the terminal apparatus performs an adjustment process to adjust the audio information so as to increase a volume of the call audio that is inputted to and outputted from the terminal apparatus according to a volume of call audio inputted at the terminal apparatus or a distance from the terminal apparatus to a user.

2. The call system according to claim 1, wherein when performing the adjustment process, the server apparatus or the terminal apparatus determines the user who emits the call audio based on a captured image of the user using the terminal apparatus and another user.

3. The call system according to claim 2, wherein the server apparatus or the terminal apparatus starts the adjustment process based on past information about the user.

4. The call system according to claim 1, wherein when performing the adjustment process, the server apparatus or the terminal apparatus detects the distance from the terminal apparatus to the user based on a captured image of the user.

5. The call system according to claim 4, wherein when performing the adjustment process, the server apparatus or the terminal apparatus determines the user who is focused on the call audio based on a captured image of the user using the terminal apparatus and another user.

6. A terminal apparatus comprising:
an input/output interface configured to input and output call audio;
a communication interface; and
a controller configured to transmit and receive audio information including the call audio via the communication interface, wherein
the controller performs an adjustment process to adjust the audio information so as to increase a volume of the call audio that is inputted to and outputted from the terminal apparatus according to a volume of inputted call audio or a distance from the terminal apparatus to a user.

7. The terminal apparatus according to claim 6, wherein when performing the adjustment process, the controller determines the user who emits the call audio based on a captured image of the user and another user.

8. The terminal apparatus according to claim 7, wherein the controller starts the adjustment process based on past information about the user.

9. The terminal apparatus according to claim 6, wherein when performing the adjustment process, the controller detects the distance to the user based on a captured image of the user.

10. The terminal apparatus according to claim 9, wherein when performing the adjustment process, the controller determines the user who is focused on the call audio based on a captured image of the user and another user.

11. An operating method of a call system comprising a terminal apparatus capable of inputting and outputting call audio and a server apparatus configured to relay transmission and reception of audio information including the call audio between the terminal apparatus and another terminal apparatus, the operating method comprising:
performing, by the server apparatus or the terminal apparatus, an adjustment process to adjust the audio information so as to increase a volume of the call audio that is inputted to and outputted from the terminal apparatus according to a volume of call audio inputted at the terminal apparatus or a distance from the terminal apparatus to a user.

12. The operating method of a call system according to claim 11, further comprising determining, by the server apparatus or the terminal apparatus when performing the adjustment process, the user who emits the call audio based on a captured image of the user using the terminal apparatus and another user.

13. The operating method of a call system according to claim 12, wherein the server apparatus or the terminal apparatus starts the adjustment process based on past information about the user.

14. The operating method of a call system according to claim 11, further comprising detecting, by the server apparatus or the terminal apparatus when performing the adjustment process, the distance from the terminal apparatus to the user based on a captured image of the user.

15. The operating method of a call system according to claim 14, further comprising determining, by the server apparatus or the terminal apparatus when performing the adjustment process, the user who is focused on the call audio based on a captured image of the user using the terminal apparatus and another user.
